(19) United States
(12) Patent Application Publication
(10) Pub. No.: US 2010/0238722 A1
(43) Pub. Date: Sep. 23, 2010

(54) NONVOLATILE SEMICONDUCTOR MEMORY DEVICES AND VOLTAGE CONTROL CIRCUIT

(75) Inventors: Toshifumi HASHIMOTO, Yokohama-Shi (JP); Takuya Futatsuyama, Yokohama-Shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/711,574

(22) Filed: Feb. 24, 2010

(30) Foreign Application Priority Data
Mar. 17, 2009 (JP) 2009-064605

(51) Int. Cl. G11C 16/06; G05F 1/10

(52) U.S. Cl. 365/185.2; 327/538

(57) ABSTRACT

A memory includes a binary-code setter BCS and the thermometer-code setter TCS, the BCS includes resistance elements with resistance values of R×2^{N} (N=integer) where a reference resistance is indicated by R with the Ns being different from each other; and transistors corresponding to the respective resistance elements, the transistors being controlled by a binary code, and the BCS has a structure obtained by connecting in parallel first structures each constituted by serially connecting a resistance element and the corresponding transistor, and the TCS includes resistance bodies each obtained by connecting in parallel resistance elements with a resistance substantially equal to any of the resistance elements in the BCS; and transistors corresponding to the resistance bodies, controlled by a thermometer code, and the TCS has a structure obtained by connecting in parallel second structures each constituted by serially connecting one of the resistance bodies and the corresponding transistor.

### CROSS-REFERENCE TO RELATED APPLICATION

This application is based upon and claims the benefit of priority from the prior Japanese Patent Applications No. 2009-64605, filed on Mar. 17, 2009, the entire contents of which are incorporated herein by reference.

### BACKGROUND OF THE INVENTION

1. Field of the Invention

The present invention relates to a nonvolatile semiconductor memory devices and a voltage control circuit, for example, to a NAND flash memory and to a circuit that controls a write voltage of a NAND flash memory.

2. Related Art

A voltage generating circuit that generates a write voltage VPGM of a NAND flash memory steps up the write voltage VPGM by a predetermined step width ΔVPGM. To reduce the step width ΔVPGM or extend an output voltage range of the write voltage VPGM, the number of bits of a digital signal for setting the write voltage VPGM needs to be increased.

According to Patent Document 1, a setting circuit receiving a thermometer code is constituted by resistance elements (4R) with a resistance ½ of a minimum resistance (for example, 8R) of resistance elements constituting a setting circuit receiving a binary code. To increase the number of bits of a digital signal for setting the write voltage VPGM in such a voltage setting circuit, low resistance elements need to be added to a voltage generating circuit.

For example, to increase the number of bits of the binary code by one bit while keeping the step width ΔVPGM fixed, the resistance element (4R) with a resistance obtained by halving the minimum resistance (8R) before the bit increase is added to the voltage setting circuit receiving the binary code. In this case, the setting circuit receiving the thermometer code needs to be constituted by resistance elements (2R) with a resistance obtained by halving the minimum resistance (4R).

As the resistance of the resistance element constituting the voltage setting circuit is reduced, however, the write voltage VPGM is affected greatly. When the resistance values of the resistance elements locally vary because of variations in manufacturing process or the like, fluctuations in the step width ΔVPGM become larger as the resistance values of the resistance elements are smaller. That is, when the number of bits of the binary code and/or the thermometer code is increased, a precise control of the step width ΔVPGM becomes difficult. This impedes downscaling of memory cells and increasing of memory cell values.

### SUMMARY OF THE INVENTION

A nonvolatile semiconductor memory device according to an embodiment of the present invention comprises: a differential amplifier comprising a first input receiving a first reference voltage and a second input receiving a comparison voltage, the differential amplifier being configured to output a voltage depending on a difference between the reference voltage and the comparison voltage; a booster configured to output a boosted voltage; a boost control portion configured to control the booster depending on the output voltage of the differential amplifier; a feedback resistance connected between the booster and the first input; and a voltage setting portion connected between the first input and a second reference voltage, wherein

the voltage setting portion comprises a binary-code setting portion and a thermometer-code setting portion,

the binary-code setting portion comprises: a plurality of resistance elements with resistance values of R×2^{N} (N is an integer) where a certain reference resistance is indicated by R with the Ns being different from each other; and a plurality of transistors corresponding to the respective resistance elements, the transistors being configured to be controlled by a binary code, and the binary-code setting portion is configured to have a structure obtained by connecting in parallel a plurality of first structures each constituted by serially connecting one of the resistance elements and the corresponding transistor, and

the thermometer-code setting portion comprises: a plurality of resistance bodies each obtained by connecting in parallel a plurality of resistance elements with a resistance substantially equal to any of the resistance elements in the binary-code setting portion; and a plurality of transistors corresponding to the resistance bodies, configured to be controlled by a thermometer code, and the thermometer-code setting portion is configured to have a structure obtained by connecting in parallel a plurality of second structures each constituted by serially connecting one of the resistance bodies and the corresponding transistor.

A voltage control circuit according to an embodiment of the present invention comprises: a differential amplifier comprising a first input receiving a first reference voltage and a second input receiving a comparison voltage, the differential amplifier being configured to output a voltage depending on a difference between the reference voltage and the comparison voltage; a booster configured to output a boosted voltage; a boost control portion configured to control the booster depending on the output voltage of the differential amplifier; a feedback resistance connected between the booster and the first input; and a voltage setting portion connected between the first input and a second reference voltage, wherein

the voltage setting portion comprises a binary-code setting portion and a thermometer-code setting portion,

the binary-code setting portion comprises: a plurality of resistance elements with resistance values of R×2^{N} (N is an integer) where a certain reference resistance is indicated by R with the Ns being different from each other; and a plurality of transistors corresponding to the respective resistance elements, the transistors being configured to be controlled by a binary code, and the binary-code setting portion is configured to have a structure obtained by connecting in parallel a plurality of first structures each constituted by serially connecting one of the resistance elements and the corresponding transistor, and

the thermometer-code setting portion comprises: a plurality of resistance bodies each obtained by connecting in parallel a plurality of resistance elements with a resistance substantially equal to any of the resistance elements in the binary-code setting portion; and a plurality of transistors corresponding to the resistance bodies, configured to be controlled by a thermometer code, and the thermometer-code setting portion is configured to have a structure obtained by connecting in parallel a plurality of second structures each constituted by serially connecting one of the resistance bodies and the corresponding transistor.

### BRIEF DESCRIPTION OF THE DRAWINGS

FIG. 1 shows an example of a voltage generating circuit of a NAND flash memory according to one embodiment of the present invention;

FIG. 2 is a table showing cases 1 to 7 that the step width ΔVPGM varies greatly;

FIG. 3 is a graph showing a relationship between the binary code, the thermometer code, and the step width ΔVPGM in the voltage control circuit disclosed in Patent Document 1;

FIG. 4 is a graph showing a relationship between the binary code, the thermometer code, and the step width ΔVPGM in the voltage control circuit according to the present embodiment;

FIGS. 5A˜5C show respectively a structure of a thermometer-code-type resistance element or a thermometer-code-type resistance body;

FIG. 6 is a graph showing a relationship between the number of the reference resistance elements Rref and the fluctuations in the step width ΔVPGM; and

FIG. 7 is a block diagram showing an example of a NAND flash memory 10 including the voltage control circuit of the present embodiment.

### DETAILED DESCRIPTION OF THE INVENTION

Embodiments of the present invention will be explained below in detail with reference to the accompanying drawings. Note that the invention is not limited thereto.

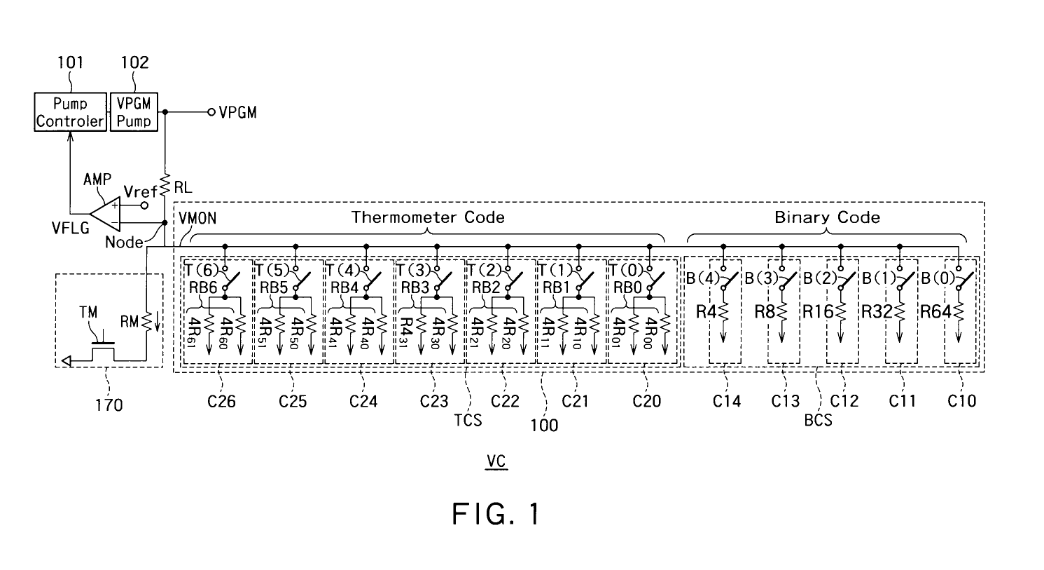

FIG. 1 shows an example of a voltage generating circuit of a NAND flash memory according to one embodiment of the present invention. The voltage generating circuit of the present embodiment can be applied to, in addition to the NAND flash memory, other nonvolatile semiconductor memory devices (hereinafter, simply “memories”).

In the nonvolatile semiconductor memory device, when data is to be written in memory cells, a write sequence is repeated by stepping up a word line voltage (also “write voltage” or “program voltage”) so that threshold voltages of a large number of memory cells fall within a target distribution. When the threshold voltages of all selected memory cells are within the target distribution, the write operation is completed. Namely, one write operation includes a plurality of write sequences.

In multivalued memories storing plural bits of data in a single memory cell, many levels of the threshold voltage need to be set. For this purpose, the target distribution of the threshold voltage needs to be set narrow. When the memory cells are downscaled, the threshold voltages of the memory cells are reduced. Accordingly, also the target distribution of the threshold voltage needs to be set narrow. To make the target distribution of the threshold voltage narrow, a step width ΔVPGM of a write voltage VPGM in each write sequence needs to be reduced. When the step width ΔVPGM is reduced, the number of write sequences repeated in one write operation is increased. Accordingly, the number of bits of a binary code and/or a thermometer code is increased.

Downscaling of the multivalued memories and the memory cells can be achieved by extending the range of the write voltage VPGM without changing the step width ΔVPGM. In this case, the range of the write voltage VPGM is extended and thus the number of write sequences repeated in one write operation is substantially increased. In both cases, it is likely that the number of bits of the binary code and/or the thermometer code is increased by storing the multivalued data in the memory cell or downscaling the memory cell.

A voltage control circuit VC according to the present embodiment has a configuration shown in FIG. 1 to suppress fluctuations in the step width ΔVPGM even if the number of bits of the binary code and/or the thermometer code is increased. The binary code is a data code representing the write voltage VPGM using a binary number. The thermometer code is data added to a higher order than the binary code and is a data code representing the write voltage VPGM using the number of “1” bits in the binary system.

The voltage control circuit VC according to the present embodiment includes a boost control circuit 101, a voltage boosting circuit (booster) 102, a differential amplifier AMP, a feedback resistance element RL, a minimum-voltage generating circuit 170, and a voltage setting circuit 100.

The voltage boosting circuit 102 is configured to output a boosted write voltage VPGM by control of the boost control circuit 101. The differential amplifier AMP includes a first input receiving a first reference voltage Vref and a second input receiving a monitor voltage VMON serving as a comparison voltage at a node Node. The differential amplifier AMP outputs a voltage VFLG depending on a difference between the first reference voltage Vref and the monitor voltage VMON. The boost control circuit 101 causes the voltage boosting circuit 102 to perform a boosting operation or stops the boosting operation of the voltage boosting circuit 102 according to the voltage VFLG.

For example, when the monitor voltage VMON is lower than the reference voltage Vref, the voltage VFLG is a positive voltage. The boost control circuit 101 thus causes the voltage boosting circuit 102 to perform the boosting operation, so that the write voltage VPGM is increased.

When the VPGM voltage is increased and the monitor voltage VMON is higher than the reference voltage Vref, the voltage VFLG is a negative voltage. The boost control circuit 101 thus stops the boosting operation of the voltage boosting circuit 102.

As described above, the voltage control circuit VC feedbacks the write voltage VPGM through the feedback resistance element RL to the differential amplifier AMP so that the monitor voltage VMON is equal to the reference voltage Vref. The voltage control circuit VC can thus output a stable write voltage VPGM.

The feedback resistance element RL is connected between an output of the voltage boosting circuit 102 and the node Node. The monitor voltage VMON is obtained by dividing the write voltage VPGM by the feedback resistance element RL, the minimum-voltage generating circuit 170, and the voltage setting circuit 100. Assume that a resistance between the node Node and a ground serving as a second reference voltage (combined resistance of the minimum-voltage generating circuit 170 and the voltage setting circuit 100) is indicated by RS. The write voltage VPGM is represented by Expression 1.

VPGM=Vref×(1+RL/RS) (Expression 1)

The minimum-voltage generating circuit 170 includes a gate transistor TM and a resistance RM for setting a minimum value of the write voltage VPGM. During the write operation, the gate transistor TM is always on. When all gate transistors in the voltage setting circuit 100 are switched off, the write voltage VPGM has a minimum value VPGM_MIN.

VPGM_MIN=Vref×(1+RL/RM) (Expression 2)

The voltage setting circuit 100 is connected between the node Node and the ground and includes a binary-code setting portion BCS and a thermometer-code setting portion TCS. The voltage setting circuit 100 controls a current flowing from a power supply with a voltage equal to the first reference voltage Vref by selecting resistance elements. A voltage decrease in the feedback resistance element RL is thus controlled and the write voltage VPGM is set.

The binary-code setting portion BCS includes a plurality of resistance elements 2^{N}R with resistance values of R×2^{N} wherein a reference resistance is indicated by R and values of N are different from each other, and a plurality of gate transistors B<0> to B<i> corresponding to the resistance elements 2^{N}R, respectively, and being controlled by a binary code. N and i are integers. Referring to FIG. 1, the binary-code setting portion BCS includes resistance elements 4R (N=2), 8R (N=3), 16R (N=4), 32R (N=5), and 64R (N=6). The resistance element 2^{N}R has a resistance value 2^{N} times the reference resistance R.

The binary-code setting portion BCS includes gate transistors B<0>, B<1>, B<2>, B<3>, and B<4>. The gate transistors B<0>, B<1>, B<2>, B<3>, and B<4> correspond to the resistance elements 64R, 32R, 16R, 8R, and 4R, respectively.

The resistance elements 64R, 32R, 16R, 8R, and 4R and the corresponding gate transistors B<0>, B<1>, B<2>, B<3>, and B<4> are serially connected to constitute first structures. For example, the gate transistor B<0> and the resistance element 64R are serially connected to each other between the node Node and the ground to constitute a first structure C10. Similarly, the gate transistor B<i> and the resistance element 2⁽⁶⁻ⁱ⁾R are serially connected to each other between the node Node and the ground to constitute the first structure C1i.

The first structures C10 to C14 are connected to each other in parallel between the node Node and the ground. The first structure C10 receives a least significant bit (LSB) of the binary code. The first structures C11 to C13 receive a second bit (second digit), a third bit (third digit), and a fourth bit (fourth digit) of the binary code, respectively. The first structure C14 receives a most significant bit (MSB) of the binary code.

When a certain bit of the binary code is “0”, the gate transistor corresponding to that bit is switched off. When a certain bit of the binary code is “1”, the gate transistor corresponding to that bit is switched on. For example, when the binary code is “10101”, the gate transistors B<3> and B<1> are switched off and the gate transistors B<4>, B<2>, and B<0> are switched on.

The resistance values of the resistance elements are arranged in the binary-code setting portion BCS so as to be doubled from the most significant bit MSB of the binary code toward the least significant bit LSB thereof, respectively. The binary-code setting portion BCS can thus change in a stepwise manner (step up) the current according to the binary code at regular intervals. As a result, the present embodiment can step up the write voltage VPGM by an equal step width ΔVPGM in a stepwise manner.

The step width ΔVPGM is represented by Expression 3.

ΔVPGM=Vref×RL/64R (Expression 3)

Namely, the step width ΔVPGM depends on the resistance element corresponding to the least significant bit LSB of the binary code (64R in this embodiment). The resistance element 64R has a maximum resistance value Rmax with a value of N largest in the binary-code setting portion BCS. Accordingly, the step width ΔVPGM can be represented by Expression 4.

ΔVPGM=Vref×RL/Rmax (Expression 4)

The thermometer-code setting portion TCS includes a plurality of resistance elements 4R00 to 4R61 with a resistance substantially equal to the resistance of the resistance element 4R which is the lowest in the binary-code setting portion BCS. The resistance elements 4R00 to 4R61 are connected in parallel in pairs to constitute resistance bodies RB0 to RB6. For example, the resistance elements 4R00 and 4R01 are connected to each other in parallel to constitute the resistance body RB0. Similarly, the resistance elements 4Ri0 and 4Ri1 are connected to each other in parallel to constitute the resistance body RBi.

The thermometer-code setting portion TCS further includes gate transistors T<0> to T<6> corresponding to the resistance bodies RB0 to RB6, respectively. The resistance bodies RB0 to RB6 and the corresponding gate transistors T<0> to T<6> are serially connected to each other to constitute second structures C20 to C 26, respectively. For example, the gate transistor T<0> and the resistance body RB0 are serially connected to each other between the node Node and the ground to constitute the second structure C20. Similarly, the gate transistor T<i> and the resistance body RBi are serially connected to each other between the node Node and the ground to constitute the second structure C2i.

The second structures C20 to C26 are connected to each other in parallel between the node Node and the ground. The second structures C20 to C26 receive a thermometer code. The thermometer code is a data code representing a value by the number of “1” bits in the binary system. For example, decimal numbers “0”, “1”, “2”, “3”, “4”, “5”, “6”, and “7” are represented as “000”, “001”, “010”, “011”, “100”, “101”, “110”, and “111” in the binary data, respectively, and as “0000000”, “0000001”, “0000011”, “0000111”, “0001111”, “0011111”, “0111111”, and “1111111” in thermometer code, respectively. Namely, seven bits of the thermometer code correspond to three bits of the binary code.

When a certain bit of the thermometer code is “0”, the gate transistor corresponding to that bit is switched off. When a certain bit of the thermometer code is “1”, the gate transistor corresponding to that bit is switched on. For example, when the thermometer code is “1010101”, the gate transistors T<5>, T<3>, and T<1> are switched off and the gate transistors T<6>, T<4>, T<2>, and T<0> are switched on.

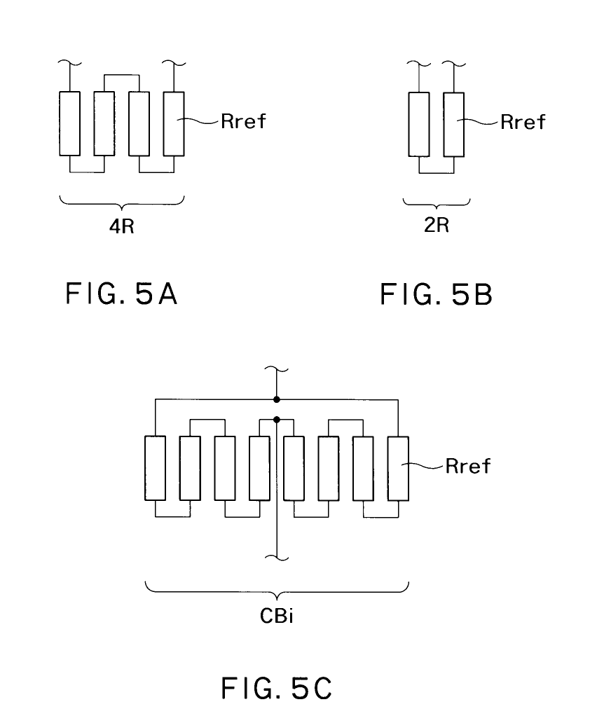

As described above, the resistance bodies RB0 to RB6 are configured by connecting in parallel two resistance elements 4Ri0 and 4R11 with the minimum resistance value in the binary-code setting portion BCS. The resistance value of the resistance bodies RB0 to RB6 thus becomes ½ of the resistance value of the minimum resistance element 4R in the binary-code setting portion BCS. Because of such configuration, fluctuations in the step width ΔVPGM are decreased. The reason will be described later with reference to FIGS. 5A to 5C.

The binary-code setting portion BCS shown in FIG. 1 can change the write voltage VPGM with 5 bits in 32 steps. The thermometer-code setting portion TCS can change the write voltage VPGM with 7 bits in 8 steps. One is carried in the thermometer code when the binary code changes from “11111” to “00000”. For example, the thermometer code changes from “0000011” to “0000111”. Accordingly, the voltage setting circuit 100 can change the write voltage VPGM in 32×8 steps in total

The write voltage VPGM is generalized by Expression 5.

VPGM=VPGM_MIN+ΔVPGM×(32×(T<6>+T<5>+T<4>+T<3>+T<2>+T<1>+T<0>)×16×B<4>+8×B<3>+4×B<2>+2B<1>+B<0>) (Expression 5)

where the gate transistors B<0> to B<4> and T<0> to T<6> are “1” in on states and “0” in off states.

According to the present embodiment, a current-adding D/A converter using the combination of the binary code and the thermometer code is utilized as the voltage setting circuit. The binary code is used for the lower bits and the thermometer code is used for the upper bits.

When the entire voltage setting circuit 100 is configured by the binary-code setting portion BCS, a low resistance element such as the reference resistance R needs to be used to increase the number of digits of a binary code. As described above, as the resistance of the resistance element is decreased, fluctuations in the step width ΔVPGM are generally increased. Accordingly, the voltage setting circuit 100 is preferably configured by resistance elements with relatively high resistance values.

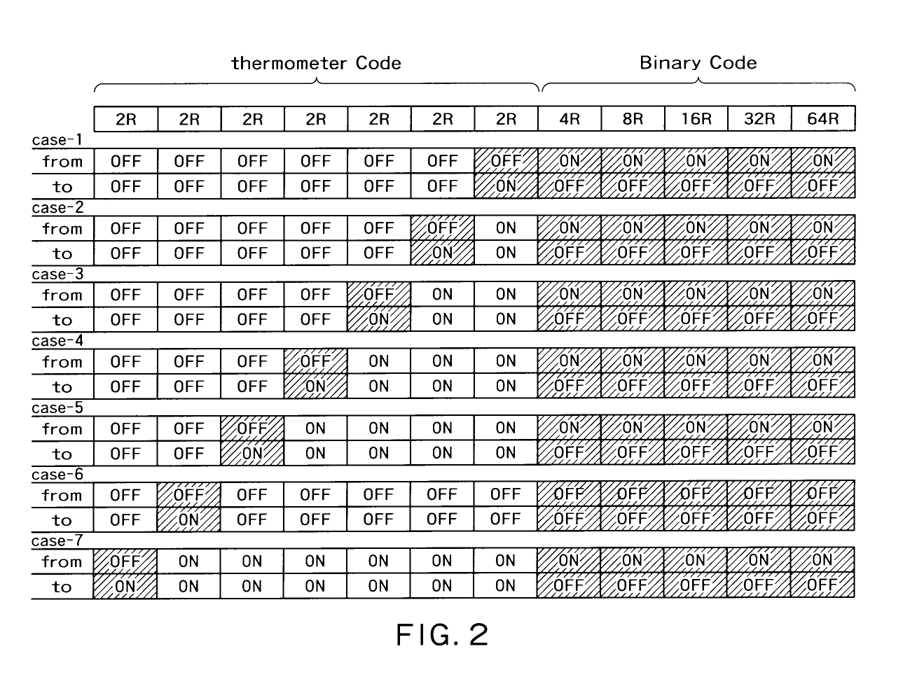

The thermometer-code setting portion in Patent Document 1 is configured using the resistance elements with a resistance value ½ of the resistance elements 4R having a smallest N in the binary-code setting portion as they are. When the number of digits of the binary code is increased while maintaining the step width ΔVPGM (while keeping 64R the least significant bit, for example), the resistance values of the resistance elements constituting the thermometer-code setting portion TCS need to be reduced. In this case, when the binary code changes from “11111” to “00000”, that is, when one is carried in the thermometer code as shown in FIG. 2, the step width ΔVPGM fluctuates greatly.

FIG. 2 is a table showing cases 1 to 7 that the step width ΔVPGM varies greatly. For example, according to the case 1, the thermometer code changes from “0000000” to “0000001” when the binary code changes from “11111” to “00000”. Similarly, in the case i, the ith bit of the thermometer code is changed from 0 to 1 when the binary code changes from “11111” to “00000”. The step width ΔVPGM fluctuates greatly in the cases 1 to 7.

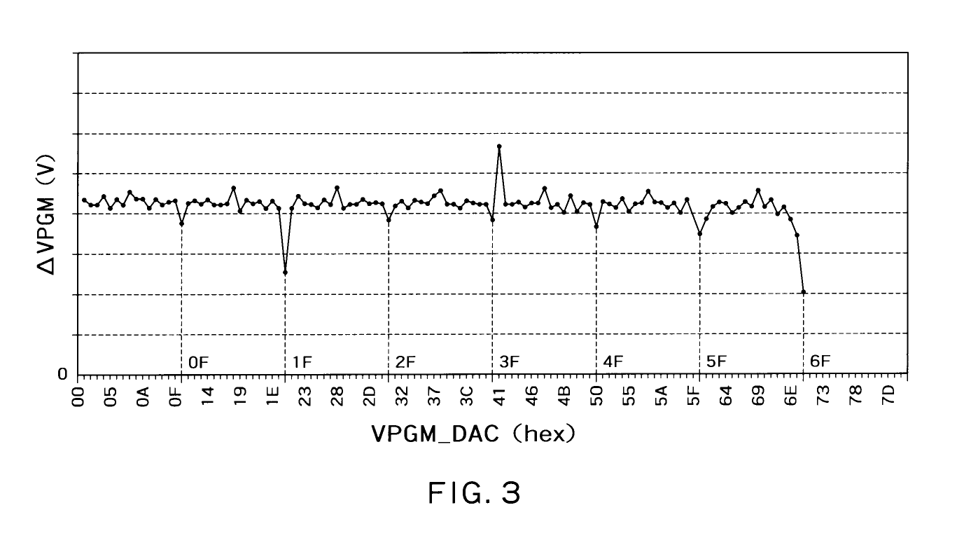

FIG. 3 is a graph showing a relationship between the binary code, the thermometer code, and the step width ΔVPGM in the voltage control circuit disclosed in Patent Document 1. A horizontal axis VPGM_DAC indicates values representing the binary code and the thermometer code by hexadecimal numbers. “1F” of VPGM_DAC corresponds to the case 1 shown in FIG. 2. “3F” of VPGM_DAC corresponds to the case 2 shown in FIG. 2. “5F” of VPGM_DAC corresponds to the case 3 shown in FIG. 2. It can be understood that fluctuations in the step width ΔVPGM are large when VPGM_DAC is “1F”, “3F”, and “5F”.

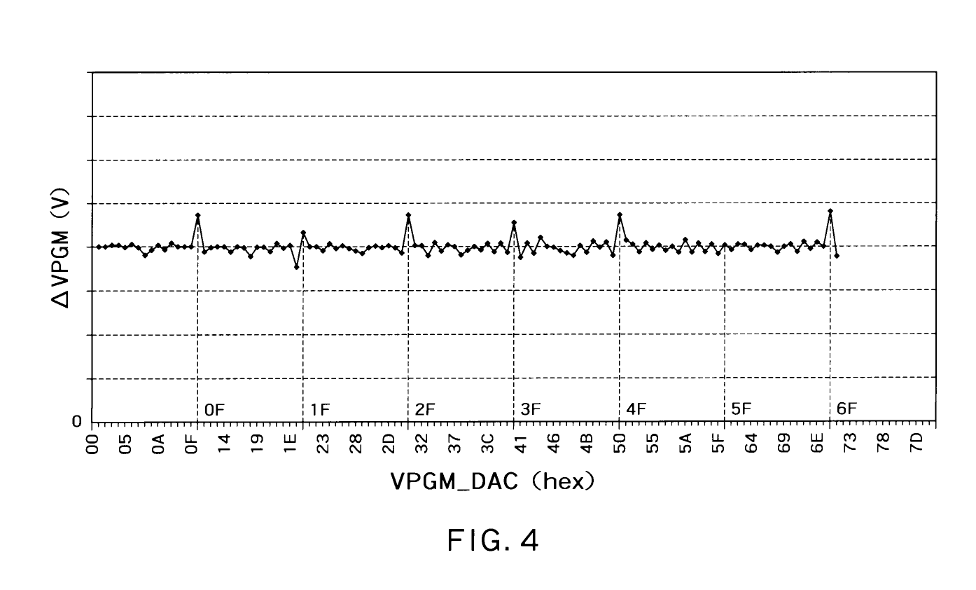

FIG. 4 is a graph showing a relationship between the binary code, the thermometer code, and the step width ΔVPGM in the voltage control circuit according to the present embodiment. It can be clearly understood that fluctuations in the step width ΔVPGM are reduced when VPGM_DAC is “1F”, “3F”, and “5F”. The reason why the fluctuations in the step width ΔVPGM are reduced is as follows.

In the present embodiment, the thermometer-code-type resistance bodies RB0 to RB6 are configured by connecting in parallel two resistance elements 4R with the minimum resistance value, which is the binary code type's most significant bit MSB. The resistance element is usually configured by serially connecting the reference resistance elements Rref with the reference resistance R as shown in FIG. 5A. For example, the resistance element 4R with a resistance of R×4 is configured by serially connecting four reference resistance elements. As shown in FIG. 5C, each of the thermometer-code-type resistance bodies RB0 to RB6 is configured by eight reference resistance elements in the present embodiment. For example, the reference resistance element is made of doped polysilicon or a diffusion layer. The doped polysilicon can be the one on the same layer as a floating gate of the memory cell.

On the other hand, the thermometer-code-type resistance element in Patent Document 1 is configured by the resistance element 2R having the resistance value ½ of the minimum resistance value which is the binary code type's most significant bit MSB. As shown in FIG. 5B, the thermometer code type resistance element in Patent Document 1 is configured by two reference resistance elements to realize the resistance value of 2R.

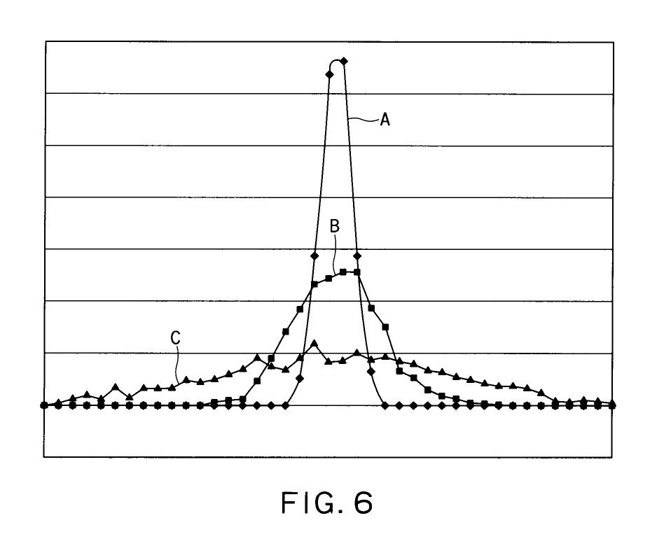

FIG. 6 is a graph showing a relationship between the number of the reference resistance elements Rref and the fluctuations in the step width ΔVPGM. When the binary code (B<0>, B<1>, B<2>, B<3>) changes from (0, 0, 0, 1) to (0, 0, 1, 0), differences ( 1/32R−− 1/64R) between reciprocals of resistance values in the binary-code setting portion BCS are distributed as shown by a curve A. When the binary code (B<0>, B<1>, B<2>, B<3>) changes from (0, 0, 1, 1) to (0, 1, 0, 0), differences ( 1/16R− 1/32R− 1/64R) between the reciprocals of the resistance values in the binary-code setting portion BCS are distributed as shown by a curve B. When the binary code (B<0>, B<1>, B<2>, B<3>) changes from (0, 1, 1, 1) to (1, 0, 0, 0), differences (⅛R− 1/16R− 1/32R− 1/64R) between the reciprocals of the resistance values in the binary-code setting portion BCS are distributed as shown by a curve C.

Assume that the voltage VMON between the node Node and the ground is fixed. The difference between the reciprocals of the resistance values in the binary-code setting portion is proportional to a difference between currents flowing in the binary-code setting portion. The curves A to C are thus similar to the distribution of fluctuations in the step width ΔVPGM when the binary code changes as described above.

Ideally, the reciprocal of the resistance value in the binary-code setting portion BCS should be increased equally by 1/64R every time when one is carried in the binary code. Namely, the write voltage VPGM should be ideally increased by a fixed step width ΔVPGM every time when one is carried in the binary code.

The resistance value R of the reference resistance element, however, fluctuates to a certain extent. When the number of reference resistance elements is reduced because of the carry in the binary code like in the curves A to C, an error in the reciprocal of the resistance value in the binary-code setting portion BCS is increased. For example, the number of reference resistance elements changes from eight to four in the curve A (when the binary code changes from (0, 0, 0, 1) to (0, 0, 1, 0)). The number of reference resistance elements changes from twelve to two in the curve B (when the binary code changes from (0, 0, 1, 1) to (0, 1, 0, 0)). The number of reference resistance elements changes from fourteen to one in the curve C (when the binary code changes from (0, 1, 1, 1) to (1, 0, 0, 0)). Namely, the rate of decrease in the number of reference resistance elements is the largest in the curve C and becomes smaller in the order of B, A. Correspondingly, the fluctuations in the step width ΔVPGM are the largest in the curve C and become smaller in the order of B, A.

It can be understood from the graph that when the rate of decrease in the number of reference resistance elements is reduced, the fluctuations in the step width ΔVPGM are also reduced. The rate of decrease in the number of reference resistance elements can be calculated by (Nb−Na)/Nb where the number of reference resistance elements connected between the node Node and the ground before the binary code is changed is indicated by Nb and the number of reference resistance elements connected between the node Node and the ground after the binary code is changed is indicated by Na.

Because the resistance body RBi in the thermometer-code setting portion TCS is constituted by the plural resistance elements R4 connected to each other in parallel in the voltage control circuit according to the present embodiment, the rate of decrease in the number of reference resistance elements becomes smaller when a digit is carried from the binary-code setting portion BCS to the thermometer-code setting portion TCS as compared to the conventional case. As a result, the fluctuations in the step width ΔVPGM can be reduced in the voltage control circuit according to the present embodiment.

As the number of reference resistance elements Rref is increased, the area of the thermometer-code setting portion TCS is increased. When the thermometer-code setting portion TCS according to the present embodiment is used, however, a precise control of the write voltage VPGM required to downscale the memory cells can be realized. Because an increase in the chip size in the present embodiment is negligibly small, the chip size is little affected. Even if the chip size of the present embodiment is not reduced, a different effect that the fluctuations in the step width ΔVPGM are reduced can be obtained.

Persons skilled in the art usually intend to make the resistance element of the thermometer-code setting portion TCS smaller (lesser) to reduce the chip size. The present inventors, however, found that by daringly increasing the number of reference resistance elements Rref constituting the thermometer-code setting portion TCS, the fluctuations in the step width ΔVPGM can be suppressed.

To obtain the resistance value of 2R, two resistance elements 4R are connected in parallel in the present embodiment. More reference resistance elements Rref can be used to obtain the resistance value of 2R. For example, four resistance elements with a resistance value of 8R in the binary-code setting portion BCS can be connected in parallel. Further, n/2 resistance elements with a resistance value of nR can be connected in parallel. In other words, while the thermometer-code setting portion TCS is constituted by resistance elements Rmin with the lowest resistance value in the binary-code setting portion BCS in the present embodiment, the thermometer-code setting portion TCS can be alternatively constituted by the resistance elements Rk with the kth (k is an integer) lowest resistance value in the binary-code setting portion BCS. In this case, the resistance body constituting the thermometer-code setting portion TCS can be configured by 2^{k} resistance elements. Rk indicates a resistance element with the kth lowest resistance value in the binary-code setting portion BCS or a resistance value thereof. Rmin indicates a resistance element with the lowest resistance value in the binary-code setting portion BCS or a resistance value thereof.

According to the present embodiment, even if the resistance value of the thermometer-code setting portion TCS is substantially decreased to reduce the step width ΔVPGM of the output voltage or to extend the range of the write voltage VPGM, the fluctuations in the step width ΔVPGM can be suppressed.

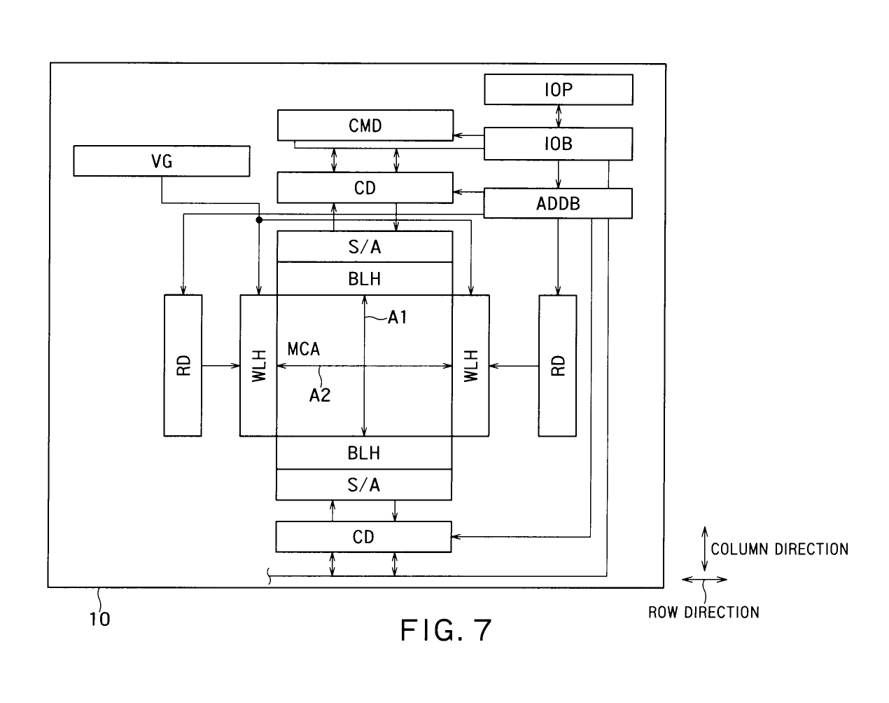

FIG. 7 is a block diagram showing an example of a NAND flash memory 10 (hereinafter, simply “the memory 10”) including the voltage control circuit of the present embodiment. The memory 10 includes a memory cell array MCA, a row decoder RD, a column decoder CD, a sense amplifier S/A, an input/output buffer IOB, a voltage generating circuit VG, an external I/O pad IOP, a bit line hookup BLH, a word line hookup WLH, a command decoder CMD, and an address buffer ADDB.

Write data, an address, and a command are inputted via the external I/O pad IOP to the input/output buffer IOB. Read data is outputted from the input/output buffer IOB via the external I/O pad IOP. The input/output buffer IOB transmits the command to the command decoder CMD, the address to the row decoder RD and the column decoder CD, and the data to a data latch in the sense amplifier S/A. The row decoder RD decodes the address and selects a word line based on an address signal. The column decoder CD decodes the address, selects a sense amplifier in the sense amplifier S/A based on the address signal, and transfers the read data latched by the selected sense amplifier to a data bus or the externally received write data to the selected sense amplifier. The sense amplifier S/A consists of a plurality of sense amplifiers corresponding to the respective bit lines. The configuration of the sense amplifier S/A can be an already known one.

The voltage generating circuit VG receives a voltage level setting signal to generate internal voltages such as a reference voltage Vref for reference, an internal step-down supply voltage VDD, and a write voltage VPGM from an externally supplied supply voltage VCC. The voltage generating circuit VG supplies the internal voltages to the row decoder RD, the column decoder CD, the sense amplifier S/A, and a cell source driver CSD. The voltage control circuit VC according to the present embodiment is provided in the voltage generating circuit VG.

The word line hookup WLH applies the write voltage VPGM from the voltage generating circuit VG to a selected word line. To change the selected word line, the word line hookup WLH changes connection between the word line WL and the row decoder RD. Thus, voltage control circuit VC according to the present embodiment can be applied to the NAND flash memory.

1. A nonvolatile semiconductor memory device comprising:
a differential amplifier comprising a first input receiving a first reference voltage and a second input receiving a comparison voltage, the differential amplifier being configured to output a voltage depending on a difference between the reference voltage and the comparison voltage;
a booster configured to output a boosted voltage;
a boost control portion configured to control the booster depending on the output voltage of the differential amplifier;
a feedback resistance connected between the booster and the first input; and
a voltage setting portion connected between the first input and a second reference voltage, wherein
the voltage setting portion comprises a binary-code setting portion and a thermometer-code setting portion,
the binary-code setting portion comprises: a plurality of resistance elements with resistance values of R×2^{N} (N is an integer) where a certain reference resistance is indicated by R with the Ns being different from each other; and a plurality of transistors corresponding to the respective resistance elements,
the transistors being configured to be controlled by a binary code, and the binary-code setting portion is configured to have a structure obtained by connecting in parallel a plurality of first structures each constituted by serially connecting one of the resistance elements and the corresponding transistor, and the thermometer-code setting portion comprises: a plurality of resistance bodies each obtained by connecting in parallel a plurality of resistance elements with a resistance substantially equal to any of the resistance elements in the binary-code setting portion; and a plurality of transistors corresponding to the resistance bodies, configured to be controlled by a thermometer code, and the thermometer-code setting portion is configured to have a structure obtained by connecting in parallel a plurality of second structures each constituted by serially connecting one of the resistance bodies and the corresponding transistor.

2. The device of claim 1, wherein the binary-code setting portion is configured to flow a current through the resistance element connected to at least one of the transistors selected according to the binary code so as to control a current flowing through the feedback resistance and set the voltage outputted from the booster in a stepwise manner, and
the thermometer-code setting portion is configured to flow a current through the resistance body connected to at least one of the transistors selected according to the thermometer code so as to control the current flowing through the feedback resistance and set the voltage outputted from the booster in a stepwise manner.

3. The device of claim 2, wherein each of the resistance bodies is constituted by connecting in parallel two resistance elements with a resistance substantially equal to that of a resistance element with a smallest one of the Ns in the binary-code setting portion.

4. The device of claim 2, wherein when the voltage outputted from the booster is indicated by VPGM, the first reference voltage is indicated by Vref, a resistance value of the feedback resistance is indicated by RL, and a resistance value of a resistance element with a largest one of the Ns in the binary-code setting portion is indicated by Rmax, a step width ΔVPGM of the VPGM is represented by ΔVPGM=Vref×(RL/Rmax).

5. The device of claim 3, wherein when the voltage outputted from the booster is indicated by VPGM, the first reference voltage is indicated by Vref, a resistance value of the feedback resistance is indicated by RL, and a resistance value of a resistance element with a largest one of the Ns in the binary-code setting portion is indicated by Rmax, a step width ΔVPGM of the VPGM is represented by ΔVPGM=Vref×(RL/Rmax).

6. The device of claim 2, wherein the resistance elements in the binary-code setting portion have resistance values R×2^{k} (k is an integer), R×2^{k-1}, R×2^{k-2}, R×2^{k-3}, onwards corresponding to respective bits from a lower one to an upper one of the binary code.

7. The device of claim 3, wherein the resistance elements in the binary-code setting portion have resistance values R×2^{k} (k is an integer), R×2^{k-1}, R×2^{k-2}, R×2^{k-3}, onwards corresponding to respective bits from a lower one to an upper one of the binary code.

8. The device of claim 4, wherein the resistance elements in the binary-code setting portion have resistance values R×2^{k} (k is an integer), R×2^{k-1}, R×2^{k-2}, R×2^{k-3}, onwards corresponding to respective bits from a lower one to an upper one of the binary code.

9. The device of claim 2, wherein the N of the resistance element corresponding to a least significant bit of the binary code is largest among the resistance elements in the binary-code setting portion, and
the N of the resistance element corresponding to a most significant bit of the binary code is smallest among the resistance elements in the binary-code setting portion.

10. The device of claim 3, wherein the N of the resistance element corresponding to a least significant bit of the binary code is largest among the resistance elements in the binary-code setting portion, and
the N of the resistance element corresponding to a most significant bit of the binary code is smallest among the resistance elements in the binary-code setting portion.

11. The device of claim 4, wherein the N of the resistance element corresponding to a least significant bit of the binary code is largest among the resistance elements in the binary-code setting portion, and
the N of the resistance element corresponding to a most significant bit of the binary code is smallest among the resistance elements in the binary-code setting portion.

12. The device of claim 5, wherein the N of the resistance element corresponding to a least significant bit of the binary code is largest among the resistance elements in the binary-code setting portion, and
the N of the resistance element corresponding to a most significant bit of the binary code is smallest among the resistance elements in the binary-code setting portion.

13. The device of claim 4, wherein the voltage setting portion increases the VPGM from a predetermined minimum value by the step width ΔVPGM.

14. The device of claim 5, wherein the voltage setting portion increases the VPGM from a predetermined minimum value by the step width ΔVPGM.

15. The device of claim 4, wherein the VPGM is a write voltage of a NAND flash memory.

16. The device of claim 13, wherein the VPGM is a write voltage of a NAND flash memory.

17. A voltage control circuit comprising:
a differential amplifier comprising a first input receiving a first reference voltage and a second input receiving a comparison voltage, the differential amplifier being configured to output a voltage depending on a difference between the reference voltage and the comparison voltage;
a booster configured to output a boosted voltage;
a boost control portion configured to control the booster depending on the output voltage of the differential amplifier;
a feedback resistance connected between the booster and the first input; and
a voltage setting portion connected between the first input and a second reference voltage, wherein
the voltage setting portion comprises a binary-code setting portion and a thermometer-code setting portion,
the binary-code setting portion comprises: a plurality of resistance elements with resistance values of R×2^{N} (N is an integer) where a certain reference resistance is indicated by R with the Ns being different from each other; and a plurality of transistors corresponding to the respective resistance elements, the transistors being configured to be controlled by a binary code, and the binary-code setting portion is configured to have a structure obtained by connecting in parallel a plurality of first structures each constituted by serially connecting one of the resistance elements and the corresponding transistor, and
the thermometer-code setting portion comprises: a plurality of resistance bodies each obtained by connecting in parallel a plurality of resistance elements with a resistance substantially equal to any of the resistance elements in the binary-code setting portion; and a plurality of transistors corresponding to the resistance bodies, configured to be controlled by a thermometer code, and the thermometer-code setting portion is configured to have a structure obtained by connecting in parallel a plurality of second structures each constituted by serially connecting one of the resistance bodies and the corresponding transistor.

18. The circuit of claim 17, wherein the binary-code setting portion is configured to flow a current through the resistance element connected to at least one of the transistors selected according to the binary code so as to control a current flowing through the feedback resistance and set the voltage outputted from the booster in a stepwise manner, and
the thermometer-code setting portion is configured to flow a current through the resistance body connected to at least one of the transistors selected according to the thermometer code so as to control the current flowing through the feedback resistance and set the voltage outputted from the booster in a stepwise manner.
